(19) United States
(12) Patent Application Publication
(10) Pub. No.: US 2018/0175143 A1
(43) Pub. Date: Jun. 21, 2018

(54) SEMICONDUCTOR DEVICE AND METHOD OF MANUFACTURING THE SAME

(71) Applicant: Samsung Electronics Co., Ltd., Suwon-si (KR)

(72) Inventors: Chan-sic YOON, Anyang-si (KR); Ki-seok Lee, Hwaseong-si (KR); Ki-wook Jung, Seoul (KR); Dong-oh Kim, Daegu (KR); Ho-in Lee, Suwon-si (KR); Je-min Park, Suwon-si (KR); Seok-han Park, Hwaseong-si (KR); Augustin Hong, Seoul (KR); Ju-yeon Jang, Hwaseong-si (KR); Hyeon-ok Jung, Daejeon (KR); Yu-jin Seo, Busan (KR)

(73) Assignee: Samsung Electronics Co., Ltd., Suwon-si (KR)

(21) Appl. No.: 15/833,031

(22) Filed: Dec. 6, 2017

(30) Foreign Application Priority Data
Dec. 19, 2016 (KR) 10-2016-0173918

(51) Int. Cl. H01L 29/06; H01L 27/092; H01L 21/762

(52) U.S. Cl. CPC H01L 29/0649; H01L 21/823878; H01L 21/76224; H01L 27/092

(57) ABSTRACT

A semiconductor device including a substrate with a first trench, a first insulation liner on inner flanks of the first trench, and a second insulation liner on inner flanks of a first sub trench, the first insulation trench defined by the first insulation liner in the first trench, a top level of the second insulation liner that adjoins the inner flanks of the first sub trench in a direction perpendicular to a top surface of the substrate being different from the top surface of the substrate outside the first trench, may be provided.

### CROSS-REFERENCE TO RELATED APPLICATION

This application claims priority to Korean Patent Application No. 10-2016-0173918, filed on Dec. 19, 2016, in the Korean Intellectual Property Office, the disclosure of which is incorporated herein in its entirety by reference.

### BACKGROUND

### 1. Field

The present disclosure relates to semiconductor devices and/or a methods of manufacturing the same, and more particularly to semiconductor devices including a device isolation membrane in a substrate and/or methods of manufacturing the semiconductor device.

### 2. Description of Related Art

As the degree of integration of a semiconductor device increases, device isolation techniques for electrically isolating adjacent devices from each other are becoming more and more important. In particular, a trench-type device isolation structure is widely used for due to its narrow width and improved device isolation properties.

### SUMMARY

Some example embodiments of the present disclosure provide semiconductor devices which may reduce or prevent materials incoming from subsequent processes from remaining between a device isolation structure and an active area of a substrate and/or manufacturing methods thereof.

According to an example embodiment of the present disclosure, a semiconductor device includes a substrate with a first trench, a first insulation liner on inner flanks of the first trench, and a second insulation liner on inner flanks of a first sub trench, the first sub trench defined by the first insulation liner in the first trench, a top level of the second insulation liner that adjoins the inner flanks of the first sub trench in a direction perpendicular to a top surface of the substrate being different from the top surface of the substrate.

According to an example embodiment of the present disclosure, a semiconductor device includes a substrate including a plurality of trenches, a first insulation liner on inner flanks of each of the plurality of trenches, and a second insulation liner on inner flanks of each of a plurality of first sub trenches, each of the plurality of first sub trenches defined by the first insulation liner in each of the plurality of trenches, the second insulation liners in at least two of the plurality of the trenches having different top levels in a direction perpendicular to a top surface of the substrate.

According to an example embodiment of the present disclosure, a semiconductor device includes a substrate including a first trench, a first insulation liner along a bottom and a sidewall of the first trench, and a second insulation liner along a bottom and a sidewall of the first insulation liner inner, the second insulation liner having an etching selectivity with respect to the first insulation liner, a top level of the second insulation liner being different from a top surface of the substrate outside the first trench

### BRIEF DESCRIPTION OF THE DRAWINGS

FIG. 1A is a cross-sectional view illustrating a semiconductor device according to an example embodiment of the present disclosure.

FIG. 1B is an enlarged view of the region IB in FIG. 1A.

FIG. 1C is a cross-sectional view to explain the effects of the semiconductor device in FIG. 1A.

FIG. 1D is an enlarged view of region IB in FIG. 1C.

FIG. 1E is a cross-sectional view illustrating a semiconductor device according to an example embodiment of the present disclosure.

FIG. 2A is a cross-sectional view illustrating a semiconductor device according to an example embodiment of the present disclosure.

FIG. 2B is an enlarged view of region IIB in FIG. 2A.

FIG. 3A is a cross-sectional view illustrating a semiconductor device according to an example embodiment of the present disclosure.

FIG. 3B is an enlarged view of region IIIB in FIG. 3A.

FIGS. 3C and 3D are enlarged views according to another example embodiment corresponding to region IIIB in FIG. 3A.

FIG. 4 is a cross-sectional view illustrating a semiconductor device according to an example embodiment of the present disclosure.

FIGS. 5A through 5G are cross-sectional views showing a manufacturing process of a semiconductor device according to an example embodiment of the present disclosure.

FIGS. 6A and 6B are cross-sectional views showing a manufacturing process of semiconductor device according to another example embodiment of the present disclosure.

FIGS. 7A through 7J are cross-sectional views showing a manufacturing process of a semiconductor device according to still another example embodiment of the present disclosure.

FIGS. 8A through 8E are cross-sectional views showing a manufacturing process of a semiconductor device according to yet another example embodiment of the present disclosure.

### DETAILED DESCRIPTION

Hereinafter, referring to attached drawings, some example embodiments of the present disclosure will be described in detail. Same or similar reference numbers may be used for same elements in attached drawings, and repeated descriptions may be omitted.

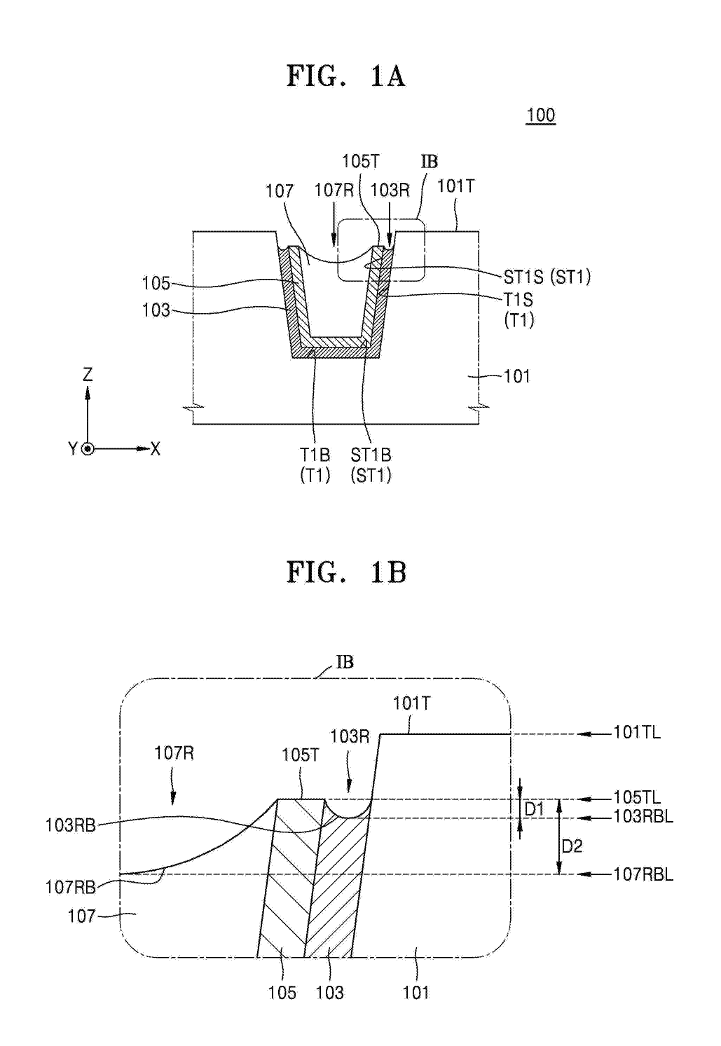

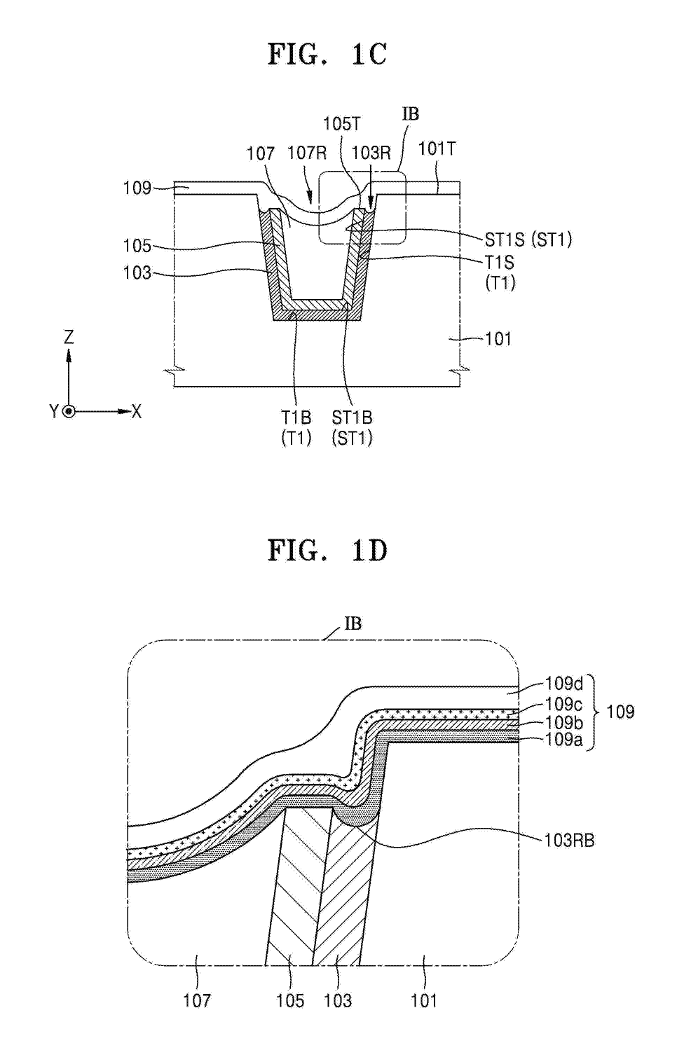

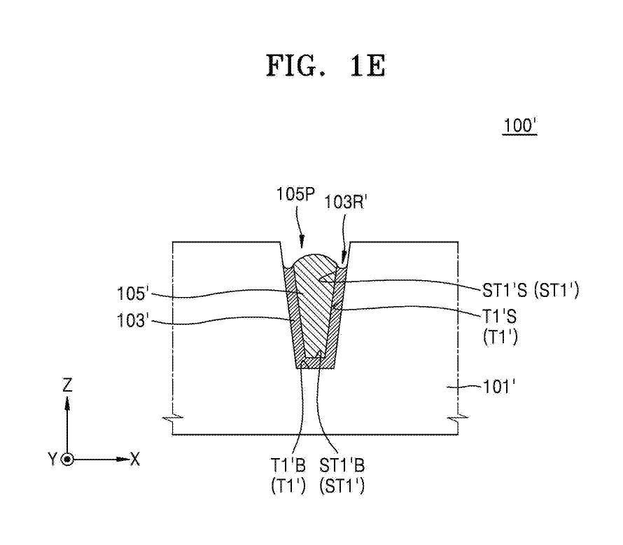

FIG. 1A is a cross-sectional view illustrating a semiconductor device 100 according to an example embodiment of the present disclosure. FIG. 1B is an enlarged view of the region IB in FIG. 1A. FIG. 1C is a cross-sectional view explaining the effects of the semiconductor device 100 in FIG. 1A. FIG. 1D is an enlarged view of the region IB in FIG. 1C.

Referring to FIGS. 1A and 1B, the semiconductor device 100 may include a substrate 101 including a trench T1, a first insulation liner 103 formed on a bottom T1B and inner flanks T1S of the trench T1, a second insulation liner 105 formed on a bottom ST1B and inner flanks ST1S of a first sub trench ST1, which is produced by forming the first insulation liner 103 in the trench T1, and a buried insulation layer 107 which fills the trench T1 on the second insulation liner 105. In this case, a level 105TL of a top 105T of the second insulation liner 105, which adjoins the inner flanks ST1S of the first sub trench ST1 in a direction perpendicular or substantially perpendicular to a top 101T of the substrate 101, may be different from a level 101TL of the top 101T of the substrate 101.

For example, the substrate 101 may include the trench T1 defining an active area. The substrate 101 may be a silicon substrate, a silicon-germanium (Si—Ge) substrate or a silicon-on-insulation substrate (SOI), etc., but example embodiments are not limited thereto. A profile of the inner flanks of the trench T1 may have a positive slope, but example embodiments are not limited thereto.

The first insulation liner 103 may be formed above the bottom T1B and the inner flanks T1S of the trench T1. The first insulation liner 103 may be an oxide film. For example, the first insulation liner 103 may be a medium temperature oxide MTO oxide film, a high density plasma (HDP)-oxide film, a thermal oxide film, a tetraethyloxysilane (TEOS)-oxide film, or an undoped silicate glass (USG)-oxide film, but example embodiments are not limited thereto. In order to increase an insulating ability, the first insulation liner 103 may be formed between the buried insulation layer 107 and the active area of the substrate 101.

The second insulation liner 105 may be formed on the bottom ST1B and the inner flanks ST1S of the first sub trench ST1 which is produced by forming the first insulation liner 103 in the trench T1. The second insulation liner 105 may be formed of a material having an etching selectivity with respect to the first insulation liner 103. In some example embodiments, the first insulation liner 103 may be an oxide film, and the second insulation liner 105 may be a nitride film. In this case, the second insulation liner 105 may be an undoped-silicon film or a silicon nitride film, however, example embodiments are not limited thereto. The second insulation liner 105 may protect the inner flanks of the trench T1 of the substrate 101 from further oxidation by subsequent processes.

The buried insulation layer 107 may be formed to bury a sub trench which is produced by forming the first insulation liner 103 and the second insulation liner 105 in the trench T1. In some example embodiments, the buried insulation layer 107 may bury only a part of the trench T1. Accordingly, the second insulation liner 105 formed on a part of the top of the inner flanks T1S of the trench T1 may be exposed.

The buried insulation layer 107 may be formed of a tonen silazane (TOSZ), a high density plasma (HDP) oxide film, or an undoped silicate glass (USG) oxide film, but example embodiments are not limited thereto. The buried insulation layer 107 may be silicate, siloxane, methyl silsesquioxane (MSQ), hydrogen silsesquioxane (HSQ), polysilazane, or a spin-on-glass (SOG) oxide film including a combination thereof. The SOG oxide film may at least partially comprise silicon, oxygen, hydrogen, or nitrogen formed in a network structure and has high flowability, and therefore, may have an improved gap-fill property.

Meanwhile, the level 105TL of the top 105T of the second insulation liner 105 which adjoins the inner flanks ST1S of the first sub trench ST1 in a direction (Z direction) perpendicular to a top 101T of the substrate 101 may be lower than a level 101TL of the top 101T of the substrate 101.

In manufacturing processes of the semiconductor device 100, the first insulation liner 103, the second insulation liner 105 and the buried insulation layer 107 forming a device isolation structure may be formed prior to forming device structures on the substrate 101. In the subsequent processes, formation processes and washing processes of material layers may be repeatedly performed on the substrate 101 including the device isolation structure. In this case, the first insulation liner 103, which is in a narrow gap between the substrate 101 and the second insulation liner 105, may be over-etched downwards along the narrow gap. In this case, a recess 103R may be formed to be deep between the substrate 101 and the second insulation liner 105. Hereinafter, such recess may be interchangeably referred to as a deep recess.

As a depth D1 of the recess 103R increases, materials from subsequent processes may remain on a bottom 103RB of the recess 103R instead of being removed by in a removal process. Referring to FIGS. 1C and 1D, in the subsequent processes, a plurality of material layers 109, for example, a gate insulation film 109a, a metal gate layer 109b, a polysilicon layer 109c, and a buried layer 109d, may be formed on the device isolation structure in order to form a transistor. When the recess 103R is deep, at least some of the gate insulation film 109a, the metal gate layer 109b, and/or the polysilicon layer 109c may remain deep in the recess 103R without being removed even in the subsequent processes.

However, in the semiconductor device 100 according to some example embodiments of the present disclosure, the level 105TL of the top 105T of the second insulation liner 105 may be lower than the level 101TL of the top 101T of the substrate 101. Thus, the recess 103R may not be formed or may be formed to have a relatively shallow depth due to a height difference between the level 105TL of the top of the second insulation liner 105 and the level 101TL of the top of the substrate 101. Accordingly, even if the materials are formed on a bottom 103RB of the recess 103R, the materials may be easily removed, a driving reliability of the semiconductor device 100 may be secured, and defects may be reduced or prevented. Referring again to FIGS. 1C and 1D, only the gate insulation film 109a may remain in the recess 103R, and the gate insulation film 109a in the recess 103R may be easily removed in subsequent processes.

Meanwhile, the buried insulation layer 107 also may be etched downwards by the subsequent processes, thereby forming a recess 107R. A depth D2 of the recess 107R of the buried insulation layer 107 may be deeper than a depth D1 of the recess 103R of the first insulation liner 103. However, because the recess 107R of the buried insulation layer 107 has a large width, materials formed in a bottom 107RB of the recess 107R in the subsequent processes may be easily removed, and the bottom 107RB of the recess 107R has a level 107RBL.

FIG. 1E is a cross-sectional view illustrating a semiconductor device 100′ according to an example embodiment of the present disclosure. The semiconductor device 100′ is similar to the semiconductor device 100 in FIGS. 1A and 1B. However, due to a varying width of the trench T1′, a structure of a device isolation structure is different. Same reference numbers mean same elements, and repeated descriptions may be omitted.

Referring to FIG. 1E, the semiconductor device 100′ may include a substrate 101′ including a trench T1′, a first insulation liner 103′ formed on a bottom T1′B and inner flanks T1′S of the trench T1′, a second insulation liner 105′, which is formed on a bottom ST1′B and inner flanks ST1′S of a first sub trench ST1′ produced by forming the first insulation liner 103′ in the trench T1′, to bury the first sub trench ST1′. In this case, in a direction (Z direction) perpendicular to a top of the substrate 101′, a level of a top of the second insulation liner 105′ may be lower than a level of the top of the substrate 101′. The second insulation liner 105′ may bulge upwards to have a protrusion 105P.

By a height difference between the level of the top of the second insulation liner 105′ and the level of the top of the substrate 101′, a recess 103R′ on the first insulation liner 103′ may not be formed or may be formed to have a relatively shallow depth.

An aspect ratio of the trench T1′ of the semiconductor device 100′ in FIG. 1E may be higher than the aspect ratio of the trench T1 of the semiconductor device 100 in FIGS. 1A through 1D. In some example embodiments, the device isolation structure described with reference to FIGS. 1A through 1D may be formed in a core/peri region, and a device isolation structure included in the semiconductor device 100′ in FIG. 1E may be formed in a cell region, but example embodiments are not limited thereto.

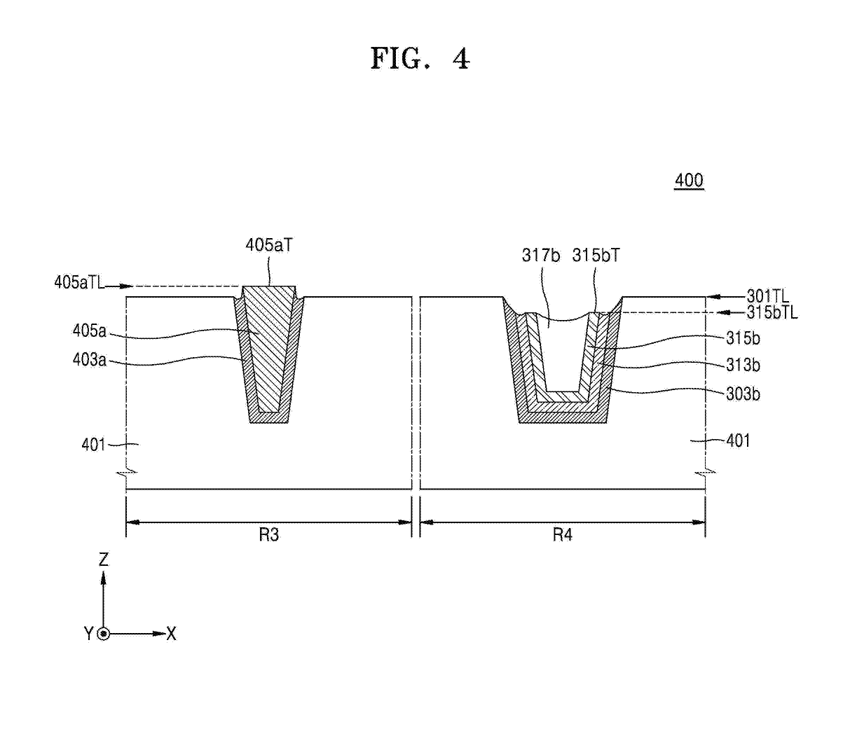

In some example embodiments, the device isolation structure included in the semiconductor device 100 in FIGS. 1A through 1D and the device isolation structure included in the semiconductor device 100′ in FIG. 1E may be formed in one semiconductor device. Descriptions thereof are given with reference to a semiconductor device 400 in FIG. 4.

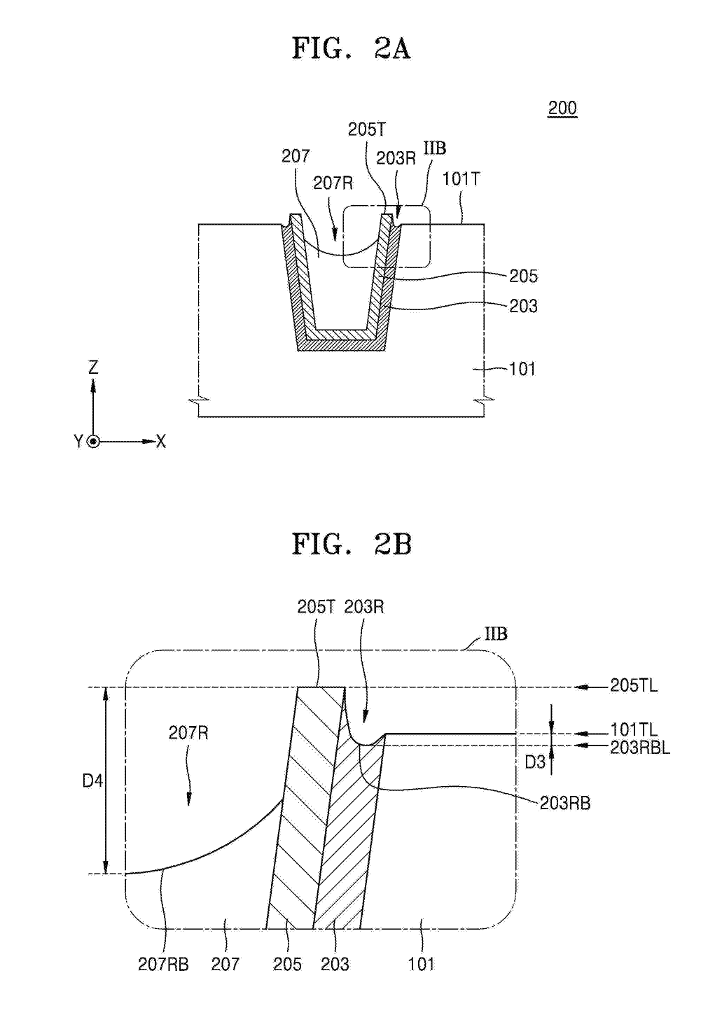

In FIGS. 1A through 1E, the level 105TL of the top 105T of the second insulation liner 105 is lower than the level 101TL of the top 101T of the substrate 101. However, some example embodiments of the present disclosure are not limited thereto. The level 105TL of the top 105T of the second insulation liner 105 may be higher than the level 101TL of the top 101T of the substrate 101. Descriptions thereof are given with reference a semiconductor device 200 illustrated in FIGS. 2A and 2B.

FIG. 2A is a cross-sectional view illustrating a semiconductor device 200 according to an example embodiment of the present disclosure. FIG. 2B is an enlarged view of region IIB in FIG. 2A. The semiconductor device 200 is the same or substantially similar to the semiconductor device 100 in FIGS. 1A and 1B except that a top 205T of a second insulation liner 205 is higher than the top 101T of the substrate 101.

Referring to FIGS. 2A and 2B, the semiconductor device 200 may include the substrate 101 including a trench, a first insulation liner 203 formed in the trench, a second insulation liner 205 formed on the first insulation liner 203, and a buried insulation layer 207 filling the trench on the second insulation liner 205. In this case, in a direction (Z direction) perpendicular to the top of the substrate 101, a level 205TL of a top 205T of the second insulation liner 205 may be higher than the level 101TL of the top of the substrate 101.

In this case, as described above, a recess 203R on the first insulation liner 203 may not be formed or may be formed to have a relatively shallow depth due to a height difference of the level 205TL of the second insulation liner 205 and the level 101TL of the substrate 101. Accordingly, materials remaining on a bottom 203RB of the recess 203R may be easily removed by the subsequent processes, a driving reliability of the semiconductor device 200 may be secured, and defects may be reduced or prevented. The bottom 203RB of the recess 203R has a level 203RBL.

Meanwhile, a depth D4 of a recess 207R of the buried insulation layer 207 may be deeper than a depth D3 of the recess 203R of the first insulation liner 203. However, because an aspect ratio of the recess 207R of the buried insulation layer 207 is much less than an aspect ratio of the recess 203R of the first insulation liner 203, materials formed in the subsequent processes and remaining in a bottom 207RB of the recess 207R of the buried insulation layer 207 may be more easily removed.

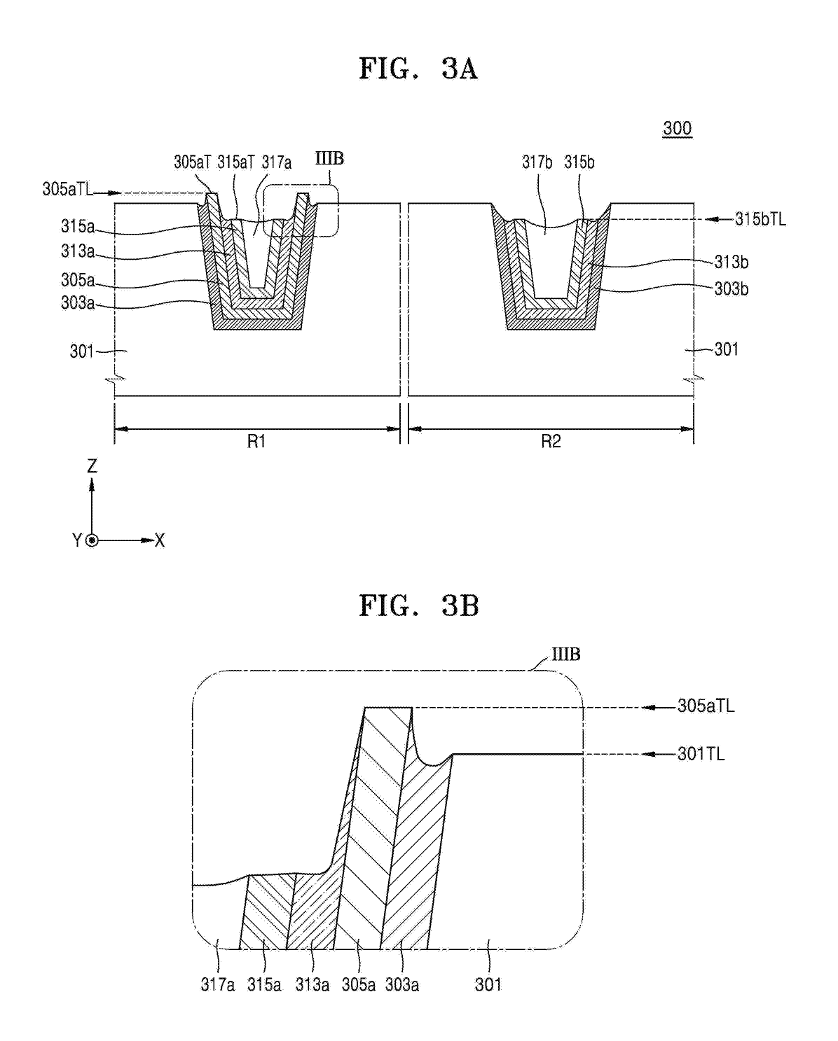

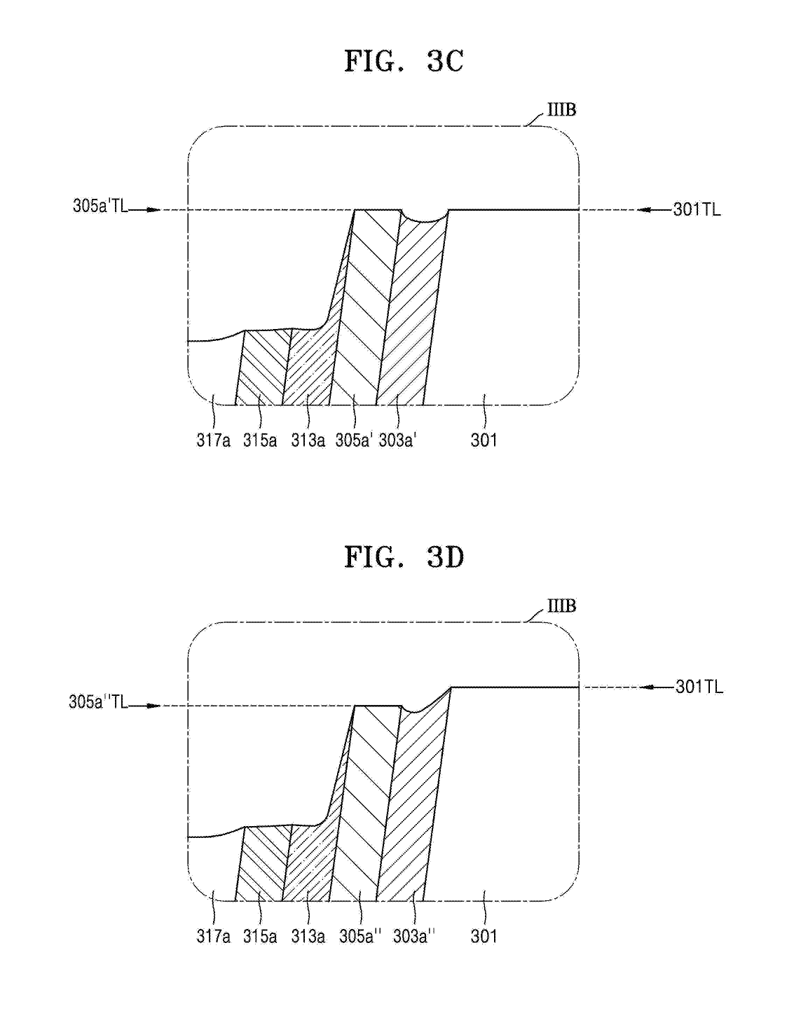

FIG. 3A is a cross-sectional view illustrating a semiconductor device 300 according to an example embodiment of the present disclosure. FIG. 3B is an enlarged view of region IIIB in FIG. 3A. FIGS. 3C and 3D are enlarged views according to another example embodiment corresponding to region IIIB in FIG. 3A. The semiconductor device 300 is the same as or similar to the semiconductor device 100 in FIGS. 1A and 1B except that the semiconductor device 300 includes device isolation structures of different compositions formed in different regions R1, R2, respectively.

Referring to FIGS. 3A and 3B, the semiconductor device 300 may include a first region R1 and a second region R2. The first region R1 and the second region R2 may be regions having different numbers of repetitions of formation processes and washing processes of material layers.

The first region R1 of the semiconductor device 300 may include a first insulation liner 303a formed in a first trench of a substrate 301, a second insulation liner 305a, a first sub insulation liner 313a, a second sub insulation liner 315a which are formed in order on the second insulation liner 305a in the first trench, and a first buried insulation layer 317a filling the first trench on the second sub insulation liner 315a.

Also, the second region R2 of the semiconductor device 300 may include a third insulation liner 303b formed in a second trench of the substrate 301, a third sub insulation liner 313b and a fourth insulation liner 315b which are formed in order on the third insulation liner 303b in the second trench, and a second buried insulation layer 317b filling the second trench on the fourth insulation liner 315b.

The first insulation liner 303a and the third insulation liner 303b may enhance an insulating ability between active areas of the substrate 301. The second insulation liner 305a and the fourth insulation liner 315b both may protect the substrate 301 from further oxidation by the subsequent processes. The first insulation liner 303a has an etching selectivity with respect to the second insulation liner 305a, and the third insulation liner 303b may have an etching selectivity with respect to the fourth insulation liner 315b. For example, the first insulation liner 303a and the third insulation liner 303b may be oxide films, and the second insulation liner 305a and the fourth insulation liner 315b may be nitride films.

Meanwhile, in a direction (Z direction) perpendicular to a top of the substrate 301, a level 315bTL of a top of the fourth insulation liner 315b is different from a level 301TL of the top of the substrate 301, and also may be different from a level 305aTL of a top 305aT of the second insulation liner 305a. In some embodiments, the first sub insulation liner 313a is on inner flanks of a sub trench defined by the second insulation liner 305a. In some embodiments, a top level of the first sub insulation liner 313a that adjoins the inner flanks of the sub trench may be substantially same as the top level of the second insulation liner 305a in a direction (Z direction) perpendicular to a top of the substrate 301. In some embodiments, a second sub insulation liner 315a is on inner flanks of a sub trench defined by the first sub insulation liner 313a.

For example, as formation processes and washing processes of the material layers following a formation process of the device isolation structure are performed in a small number of times, the first insulation liner 303a in a narrow gap between the substrate 301 and the second insulation liner 305a or the third insulation liner 303b in a narrow gap between the substrate 301 and the fourth insulation liner 315b may have little risk of being over-etched. Therefore, considering subsequent processes of each of the first region R1 and the second region R2, the level 305aTL of the top of the second insulation liner 305a in the first region R1 and a level 315bTL of the fourth insulation liner 315b in the second region R2 may be adjusted differently.

In some example embodiments, referring to FIGS. 3A and 3B, the level 305aTL of the top of the second insulation liner 305a may be higher than the level 301TL of the top of the substrate 301 and the level 315bTL of the top of the fourth insulation liner 315b.

In other example embodiments, referring to FIG. 3C, the level 305a′TL of the top of the second insulation liner 305a′ may be higher than the level 315bTL of the top of the fourth insulation liner 315b and substantially equal to the level 301TL of the top of the substrate 301. In case the formation processes and washing processes of the material layers after the formation process of the device isolation structure are repeated in a small number of times, that is, in case an over-etching of the first insulation liner 303a′ doesn't cause trouble, a structure in FIG. 3C may be applied.

In other example embodiments, referring to FIG. 3D, the level 305a′TL of the top of the second insulation liner 305a″ may be lower than the level 301TL of the top of the substrate 301 and higher than the level 315bTL of the top of the fourth insulation liner 315b. In case the number of repetitions of the subsequent processes in the first region R1 is less than the number of repetitions of the subsequent processes of the formation processes and washing processes of material layers in the second region R2, that is, in the case the first insulation liner 303a″ is expected to be over-etched less than the third insulation liner 303b, a structure in FIG. 3D may be applied.

In some example embodiments, the first region R1 may be an NMOS region and the second region R2 may be a PMOS region. In this case, as illustrated in FIG. 3A, a height difference between the level 315bTL of the top of the fourth insulation liner 315b formed in the PMOS region, which is the second region R2, and the level 301TL of the top of the substrate 301 may be greater than a height difference between the level 305aTL of the top of the second insulation liner 305a formed in the NMOS region, which is the first region R1, and the level 301TL of the top of the substrate 301.

As described above, considering the subsequent processes in each of the first region R1 and the second region R2, the semiconductor device 300 according to some example embodiments of the present disclosure may have a structure in which the levels of the tops of the second insulation liner 305a and the fourth insulation liner 315b are different. Accordingly, recesses of the first insulation liner 303a and the third insulation liner 303b in each of the first region R1 and the second region R2 may not be formed or may be formed to have a relatively shallow depth, a driving reliability of the semiconductor device 300 may be secured, and defects may be reduced or prevented.

FIG. 4 is a cross-sectional view illustrating a semiconductor device 400 according to an example embodiment of the present disclosure. The semiconductor device 400 is the same or substantially similar to the semiconductor device 300 in FIGS. 3A and 3B except that a device isolation structure formed in a first region R3.

Referring to FIG. 4, the semiconductor device 400 may include the first region R3 and a second region R4. The first region R3 and the second region R4 may be regions respectively having different numbers of repetitions of the formation processes and washing processes of material layers.

A width of a trench in the first region R3 may be less than a width of a trench in the second region R4. That is, the first region R3 of the semiconductor device 400 may include a first insulation liner 403a formed in a first trench of a substrate 401 and a second insulation liner 405a filling the first trench of the first insulation liner 403a. A device isolation structure of the second region R4 may have a same structure as the device isolation structure of the second region R2 in FIG. 3A.

The level 315bTL of the top 315bT of the fourth insulation liner 315b may be different from a level 405aTL of the top 405aT of the second insulation liner 405a, and may be lower than a level 301TL of a top of the substrate 401. However, as described in FIGS. 3A through 3D, the level 405aTL of the top of the second insulation liner 405a may be selected variously in consideration of the subsequent processes of the first region R1.

In some example embodiments, the first region R3 may be a cell region, and the second region R4 may be a core/peripheral region, but example embodiments are not limited thereto.

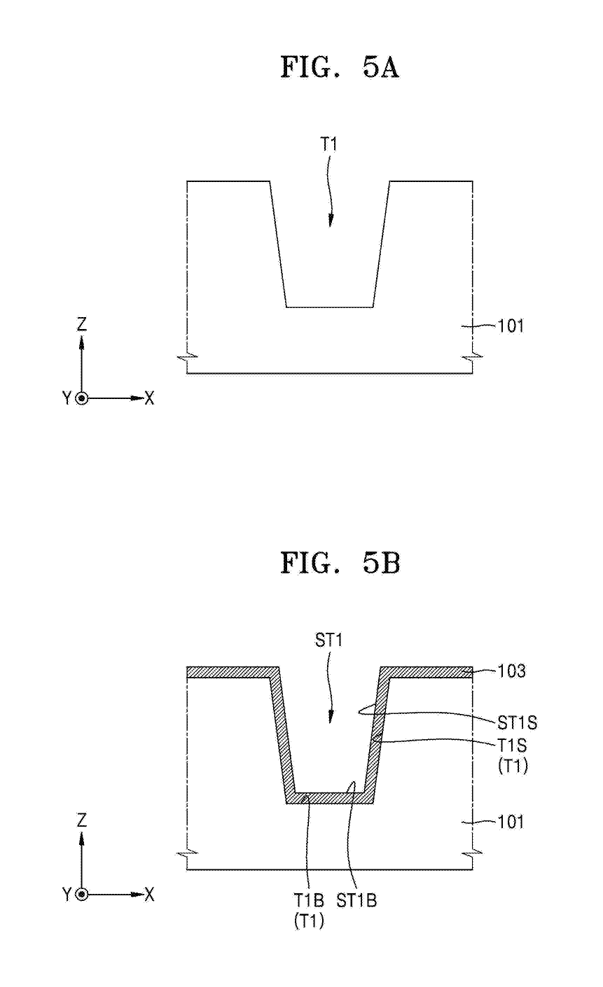

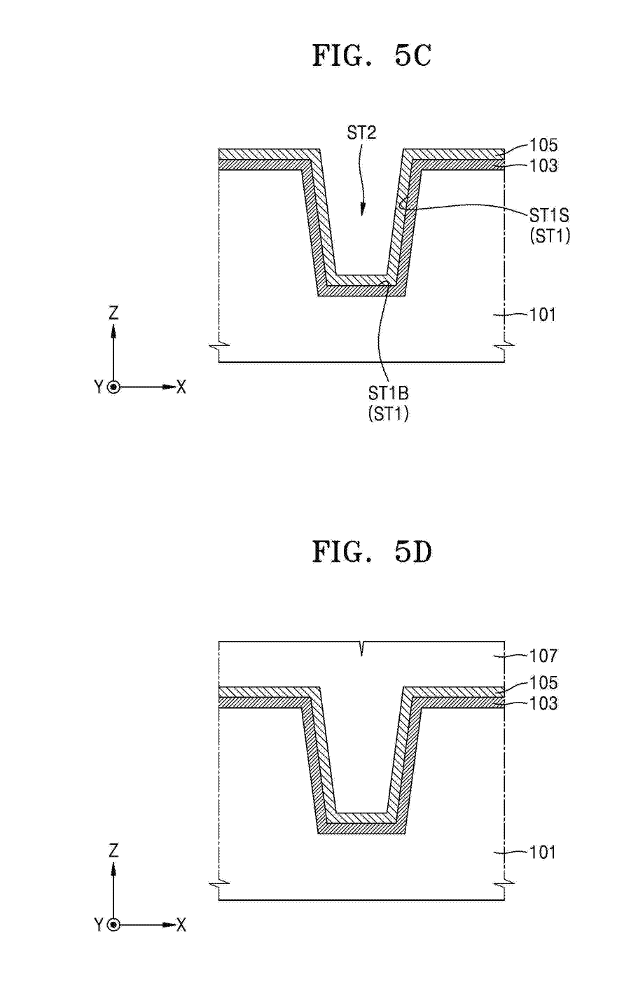

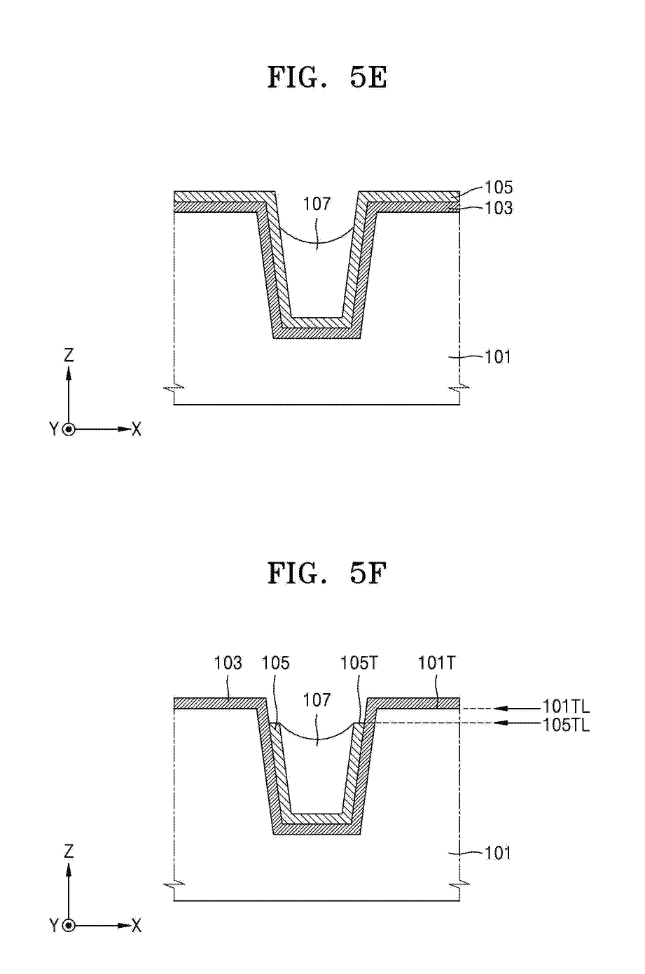

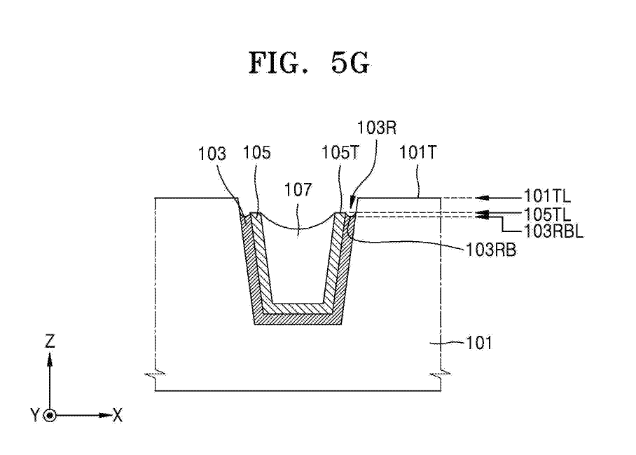

FIGS. 5A through 5G are cross-sectional views showing a manufacturing process of a semiconductor device 100 according to an example embodiment of the present disclosure.

Referring to FIG. 5A, by forming a mask pattern (not shown) on the substrate 101, and etching the substrate 101 using the mask pattern as an etching mask, the trench T1 defining the active area may be formed. In this case, a profile of the inner flanks of the trench T1 may have a positive slope, but example embodiments are not limited thereto.

Referring to FIG. 5B, the first insulation liner 103 may be formed on the bottom T1B and the inner flanks T1S of the trench T1.

Referring to FIG. 5C, the second insulation liner 105 may be formed on the bottom ST1B and the inner flanks ST1S of the first sub trench ST1, which is produced by forming the first insulation liner 103 in the trench T1. The second insulation liner 105 may be formed with materials having an etching selectivity with respect to the first insulation liner 103.

Referring to FIG. 5D, the buried insulation layer 107 may be formed on an entire surface of the substrate 101 in order to bury the sub trench which is produced by forming the first insulation liner 103 and the second insulation liner 105 in the trench T1. Because the trench T1 becomes difficult to bury as the width of the trench T1 decreases and the aspect ratio increases, the trench T1 may be buried through, for example, various piecemeal gap-fill operations. In some example embodiments, the buried insulation layer 107 may be densified through a heat treatment process.

Referring to FIG. 5E, the buried insulation layer 107 on the top of the substrate 101 may be removed by performing, for example, a planarization process on a product on which the buried insulation layer 107 is formed. For example, the buried insulation layer 107 may be flattened through a wet etch-back process, but example embodiments are not limited thereto. In some example embodiments, the buried insulation layer 107 at a part of the top of the trench T1 may be removed and bury only a part of the trench T1. Accordingly, the second insulation liner 105 formed on a part of the top of the inner flanks of the trench T1 may be exposed.

Referring to FIG. 5F, parts of the top of the second insulation liner 105 may be removed by a strip process. For example, a part of the second insulation liner 105 formed on the substrate 101 and a part of the second insulation liner 105 formed on the top of the trench T1 may be removed. In this case, the level 105TL of the top of the second insulation liner 105 in the trench T1 may be adjusted to be lower than the level 101TL of the top of the substrate 101. In the case where the first insulation liner 103 is formed of a material having an etching selectivity with respect to the second insulation liner 105, the first insulation liner 103 may remain without being significantly removed.

A height difference between the level 105TL of the top of the second insulation liner 105 and the level 101TL of the top of the substrate 101 may reduce or prevent a formation of a deep recess in the first insulation liner 103, which lies between the second insulation liner 105 and the substrate 101 in the trench T1.

Referring to FIG. 5G, parts of the top of the first insulation liner 103 may be removed by a strip process. For example, a part of the first insulation liner 103 formed on the substrate 101 and a part of the first insulation liner 103 formed on the top in the trench T1 may be removed. In this case, the first insulation liner 103 between the second insulation liner 105 and the substrate 101 may have a recess 103R sinking slightly downwards compared to the level 105TL of the top of the second insulation liner 105. Also, in this case, the bottom 103RBL of the recess 103R may be substantially same as a height of the level 105TL of the top of the second insulation liner 105.

Accordingly, by a process of adjusting the level 105TL of the top of the second insulation liner 105 to be different from the level 101TL of the top of the substrate 101, a deep recess in the first insulation liner 103 may not be formed or may be formed to have a relatively shallow depth. In this case, even if other materials remains on the bottom 103RB of the recess in subsequent processes of forming a device (e.g., transistor), the materials may be more easily removed. Accordingly, defects of the semiconductor device 100 may be reduced or prevented by controlling a device driving deterioration caused by the remaining materials. Accordingly, the semiconductor device 100 in FIGS. 1A and 1B may be manufactured.

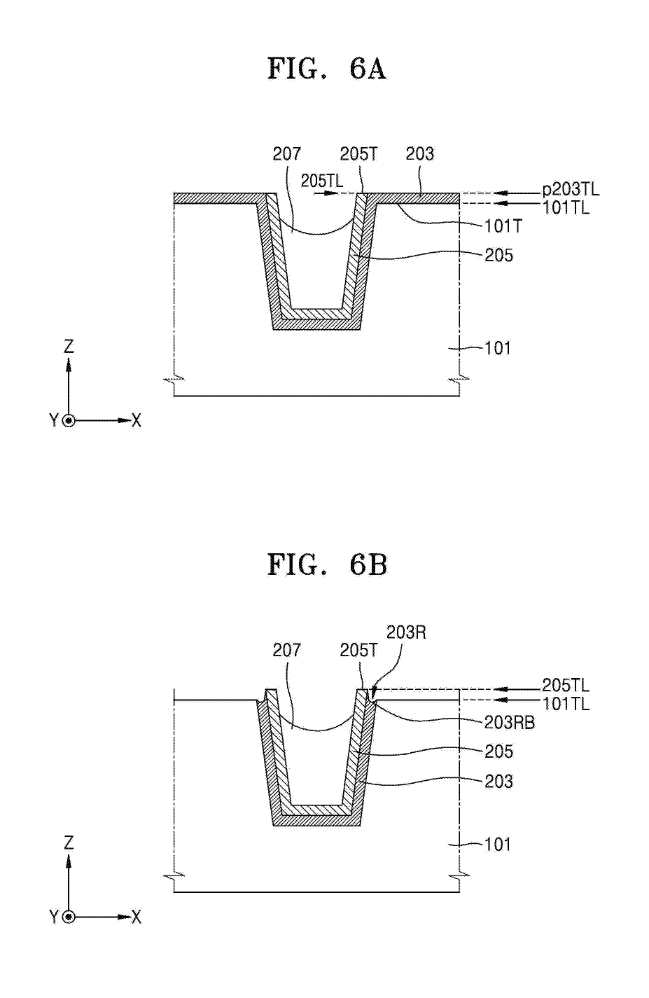

FIGS. 6A and 6B are cross-sectional views showing a manufacturing process of a semiconductor device 200 according to another example embodiment of the present disclosure. As preceding processes of FIG. 6A, processes of FIGS. 5A through 5E may be performed.

Referring to FIG. 6A, from a product of FIG. 5E, a part of the second insulation liner 205 formed on the substrate 101 may be removed by a strip process. By the process, the level 205TL of the top of the second insulation liner 205 may be substantially same as the level p203TL of the top of the first insulation liner 203. Also, the level 205TL of the top of the second insulation liner 205 may be higher than the level 101TL of the top of the substrate 101. In the case where the first insulation liner 203 is formed of the material having an etching selectivity with respect to the second insulation liner 205, the first insulation liner 203 may remain without being significantly removed.

Referring to FIG. 6B, parts of the top of the first insulation liner 203 may be removed by a strip process. For example, a part of the first insulation liner 203 formed on the substrate 101 and a part of the first insulation liner 203 formed on the top in the trench may be removed. In this case, the first insulation liner 203 between the second insulation liner 205 and the substrate 101 may have a recess 203RB sinking slightly downwards compared to the level 205TL of the top of the second insulation liner 205, but example embodiments are not limited thereto. In some example embodiments, between the second insulation liner 205 and the substrate 101, the top of the first insulation liner 203 may form a gradual slope from the top of the first insulation liner 203 to the top of the substrate 101. Accordingly, the semiconductor device 200 in FIGS. 2A and 2B may be manufactured.

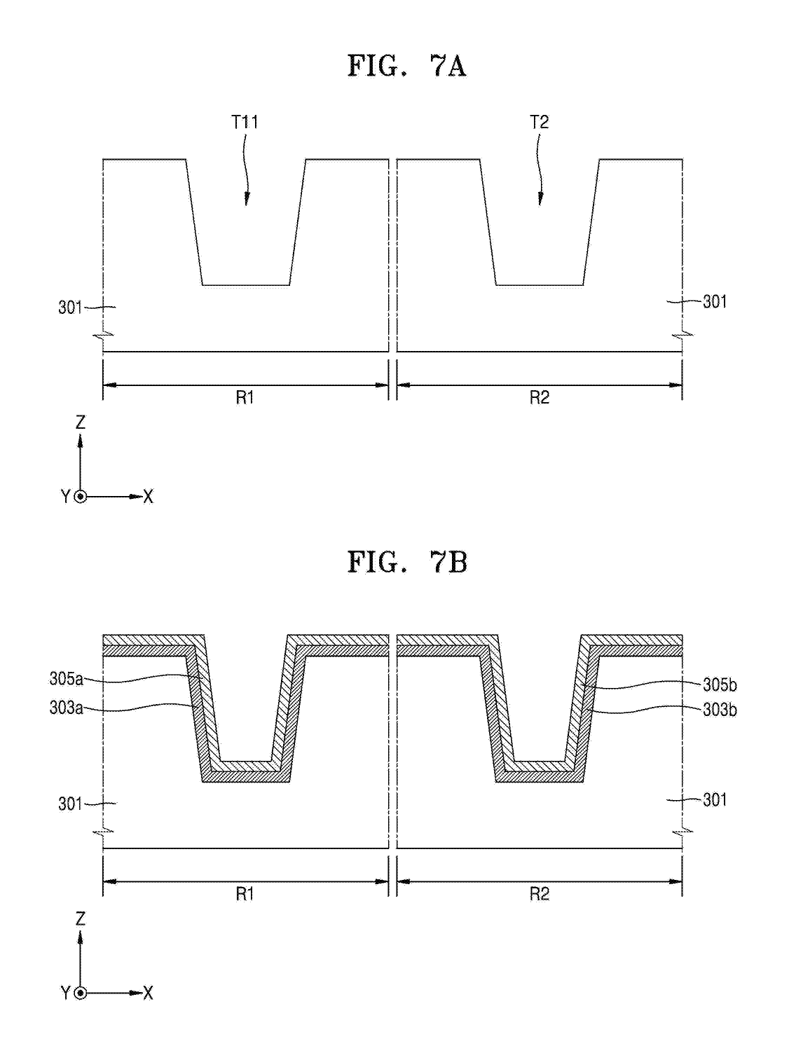

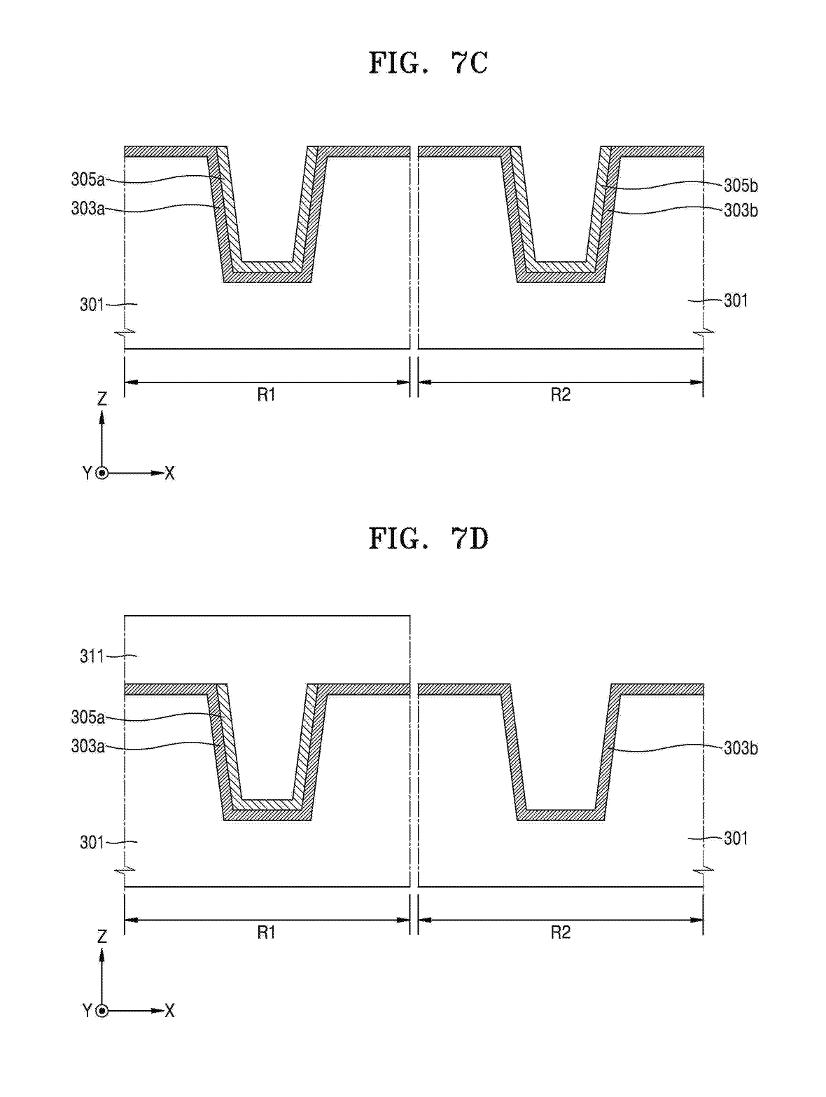

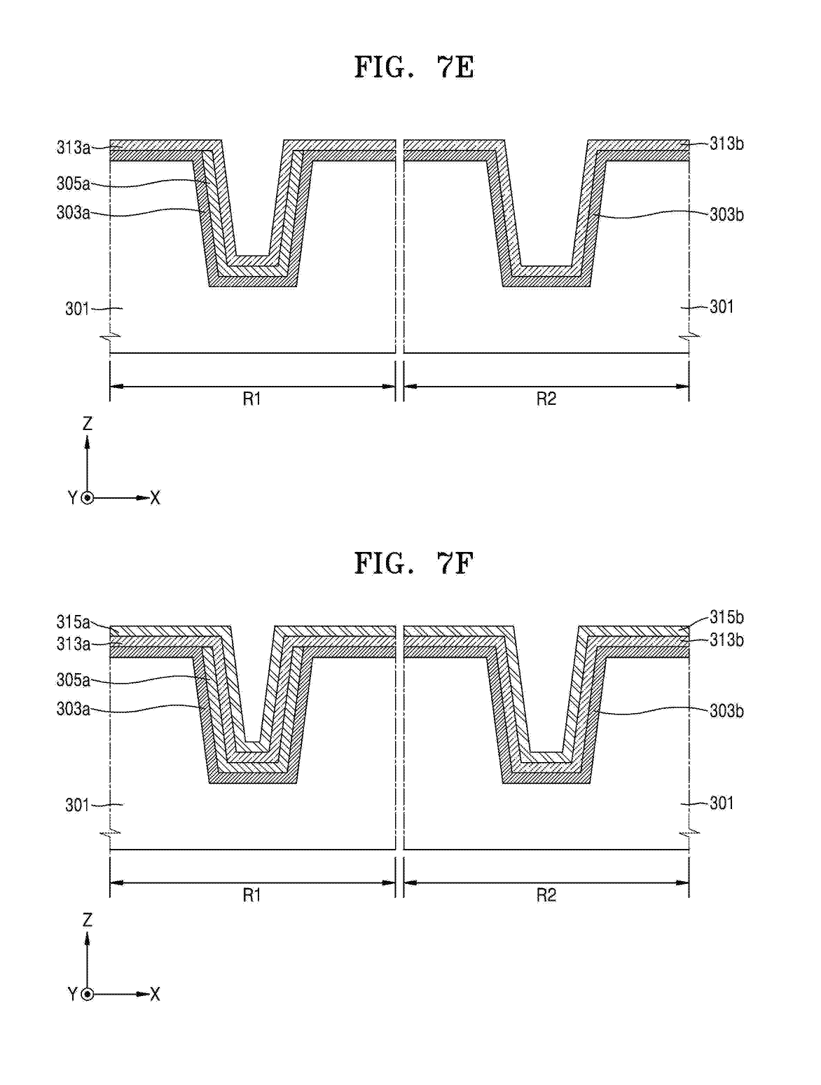

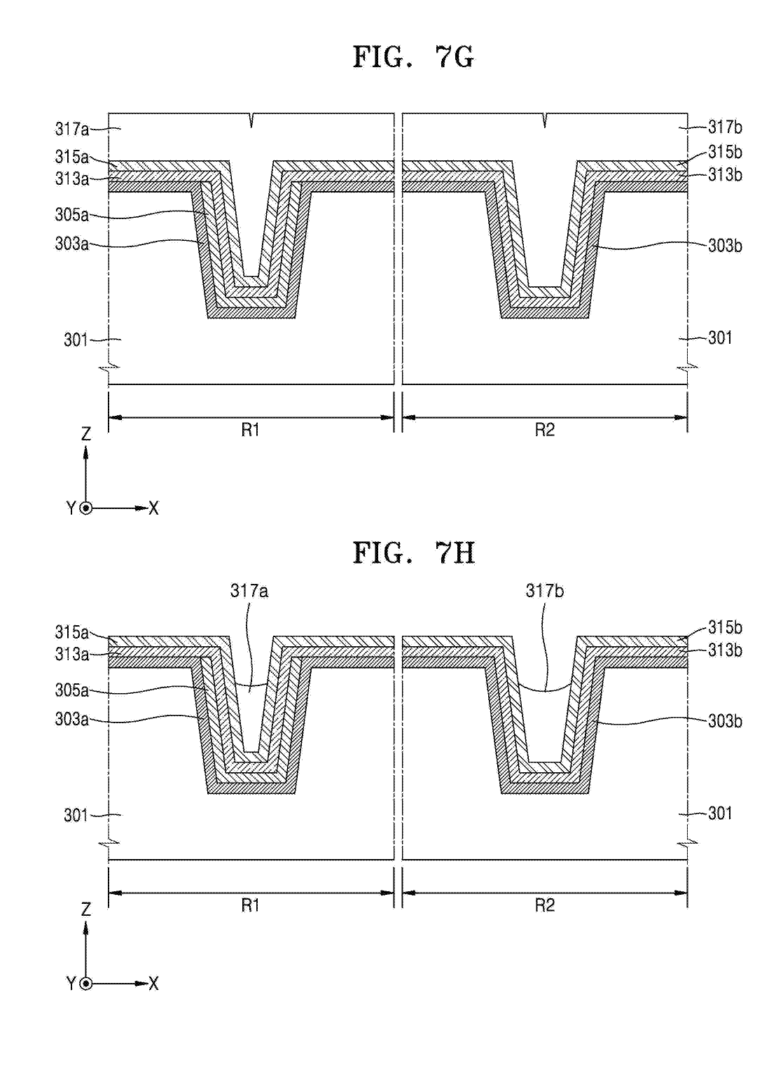

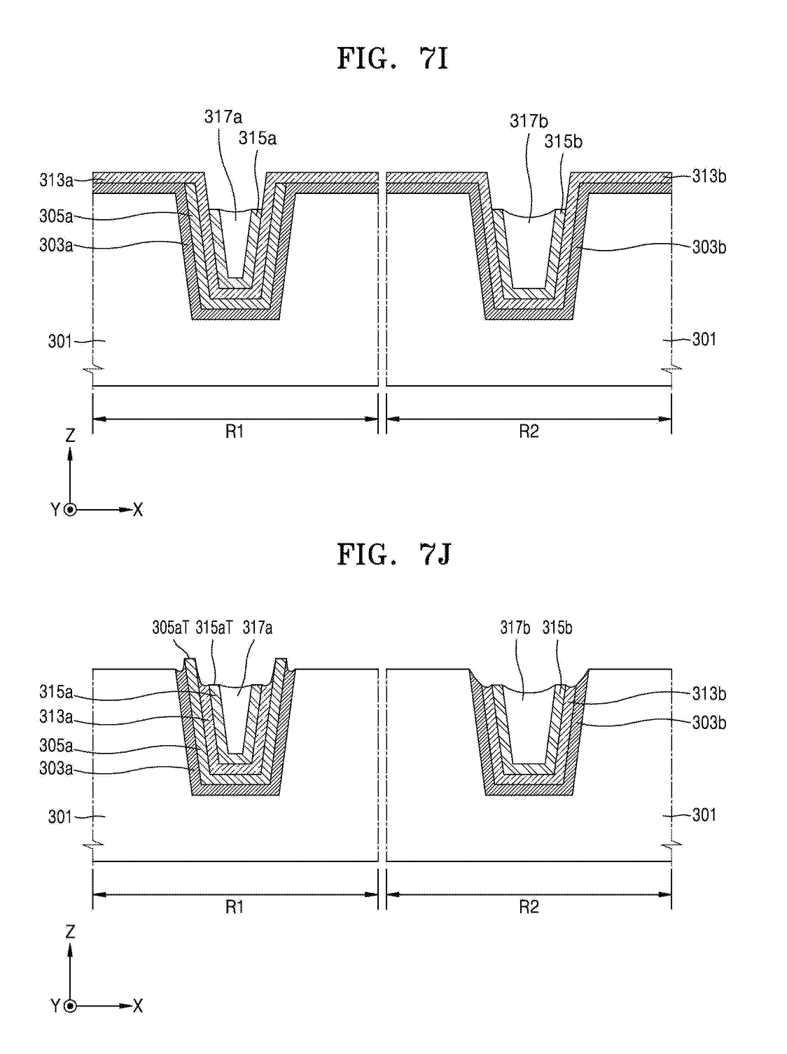

FIGS. 7A through 7J are cross-sectional views showing a manufacturing process of a semiconductor device according to still another example embodiment of the present disclosure.

Referring to FIG. 7A, by forming the mask pattern (not shown) on the substrate 301 and etching the substrate 301 using the mask pattern as an etching mask, the first trench T11 and the second trench T2 which define the active areas in the first region R1 and the second region R2, respectively, may be formed. The first trench T11 and the second trench T2 may be similar in form, however, example embodiments are not limited thereto and forms of the first trench T11 and the second trench T2 may be selected variously.

Referring to FIG. 7B, the first insulation liner 303a and the third insulation liner 303b may be respectively formed in the first region R1 and the second region R2 by forming a first insulation layer on an entire surface of the product of FIG. 7A. After that, by forming a second insulation layer which has a different etching selectivity with respect to the first insulation layer on an entire surface of the product, the second insulation liner 305a and a sacrificial liner 305b may be formed in the first region R1 and the second region R2, respectively.

Referring to FIG. 7C, parts of the second insulation liner 305a and the sacrificial liner 305b formed on a top surface of the substrate 301 may be removed by a strip process. Accordingly, the second insulation liner 305a and the sacrificial liner 305b remain only in the trench.

Referring to FIG. 7D, a photoresist 311 may be formed on the first region R1 in FIG. 7C, and the sacrificial liner 305b of the second region R2 in FIG. 7C may be completely removed by a strip process.

Referring to FIG. 7E, the first sub insulation liner 313a and the third sub insulation liner 313b may be formed in the first region R1 and the second region R2, respectively, by forming a third insulation layer on an entire surface of the product of FIG. 7D.

Referring to FIG. 7F, the second sub insulation liner 315a and the fourth insulation liner 315b may be formed in the first region R1 and the second region R2, respectively. by forming a fourth insulation layer on an entire surface of the product of FIG. 7E. The fourth insulation layer has a different etching selectivity with respect to the first sub insulation liner 313a and the third sub insulation liner 313b.

In some example embodiments, the first insulation liner 303a and the third insulation liner 303b may be formed with oxide films, the second insulation liner 305a may be formed with a nitride film, the first sub insulation liner 313a and the third sub insulation liner 313b may be formed with oxide films, the second sub insulation liner 315a and the fourth insulation liner 315b may be formed with nitride films, however, example embodiments are not limited thereto.

Referring to FIG. 7G, a first buried insulation layer 317a and a second buried insulation layer 317b burying trenches of the first region R1 and the second region R2, respectively, may be formed by forming a fifth insulation layer on an entire surface of the product of FIG. 7F. In some example embodiments, the first buried insulation layer 317a and the second buried insulation layer 317b may be densified by a heat treatment process.

Referring to FIG. 7H, the first buried insulation layer 317a and the second buried insulation layer 317b on the top of the substrate 301 may be removed by performing a planarization process on an entire surface of the product of FIG. 7F.

Referring to FIG. 7I, by performing a strip process on an entire surface of the product of FIG. 7H, a part of a top of the second sub insulation liner 315a of the first region R1 and a part of a top of the fourth insulation liner 315b of the second region R2 may be removed. In this case, a degree of the strip process may be adjusted to make a level of the top of the fourth insulation liner 315b lower than the level of the top of the substrate 301.

Referring to FIG. 7J, by performing a strip process on an entire surface of the product in FIG. 7I, the first insulation liner 303a and the first sub insulation liner 313a in the first region R1 and a part of the top of the third sub insulation liner 313b and the third insulation liner 303b in the second region R2 may be removed. In this case, due to a height difference of the top of the substrate 301 and the top of the fourth insulation liner 315b, a deep recess may not be formed on the third insulation liner 303b. Accordingly, the semiconductor device 300 in FIGS. 3A and 3B may be manufactured. The semiconductor device in FIGS. 3C and 3D may also adjust the level of the top of the second insulation liner 305a′, 305a″ by adjusting the degree of the strip process of FIG. 7C.

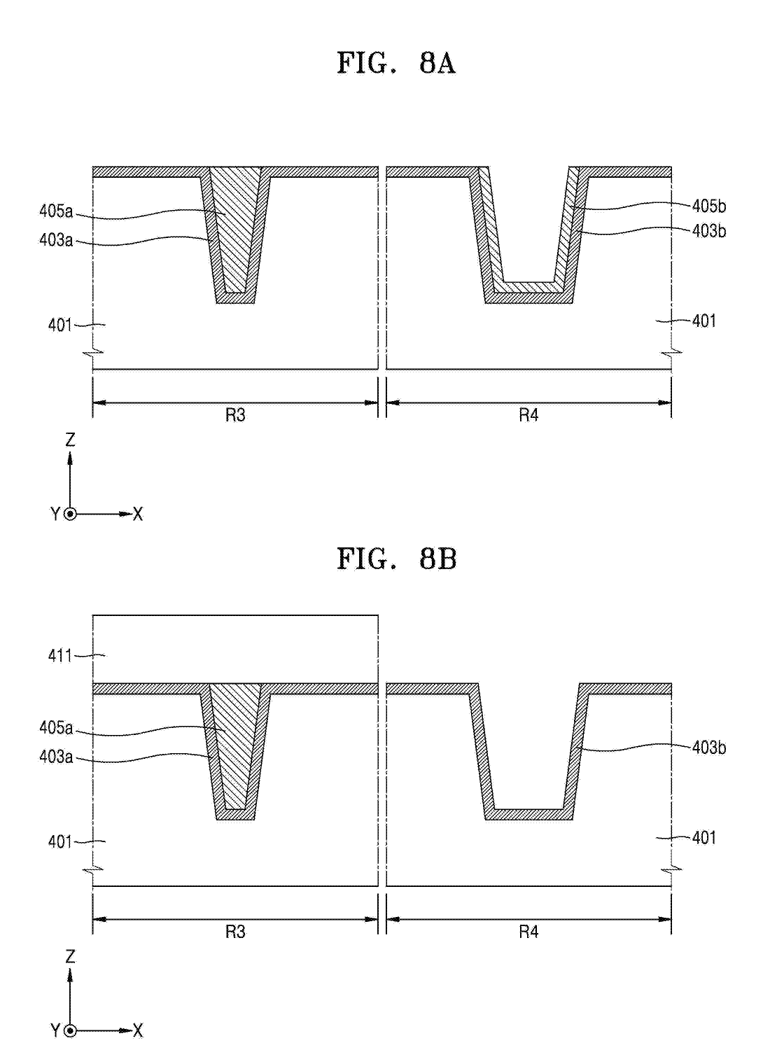

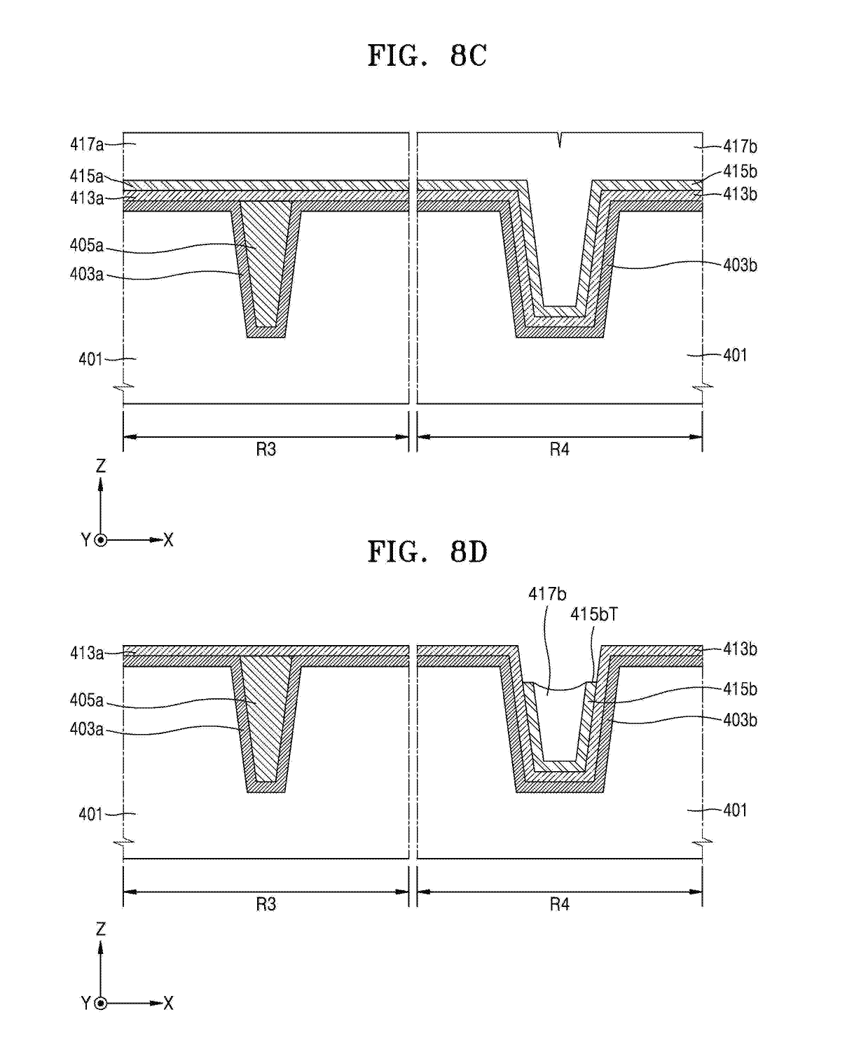

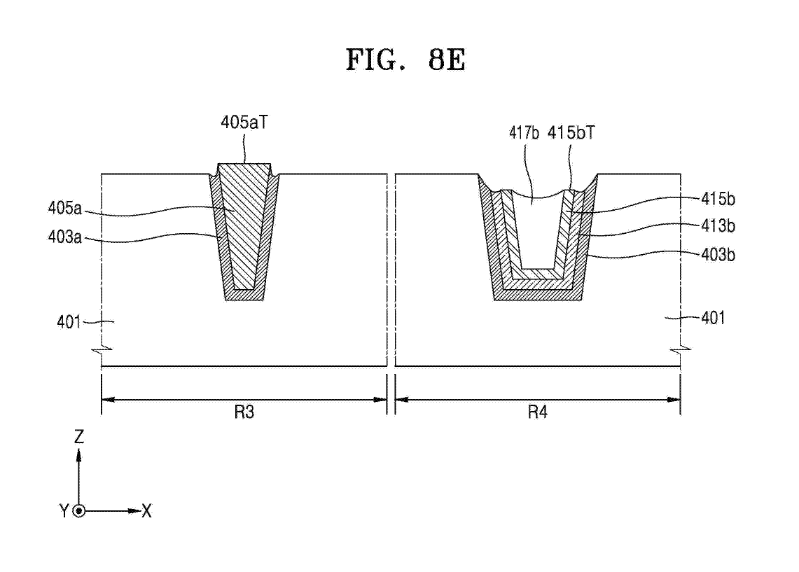

FIGS. 8A through 8E are cross-sectional views showing a manufacturing process of a semiconductor device 400 according to yet another example embodiment of the present disclosure. This manufacturing method is the same or substantially similar to the manufacturing method illustration in FIGS. 5A through 5E, and repeated descriptions thereof may be simplified.

Referring to FIG. 8A, the first trench and the second trench having different widths may be formed in the first region R3 and the second region R4 of the substrate 401, respectively. Next, the first insulation liner 403a and the third insulation liner 403b may be formed in the first region R3 and the second region R4, respectively, by forming the first insulation layer on an entire surface of a product. After this, the second insulation liner 405a and a first sacrificial liner 405b may be formed in the first region R3 and the second region R4, respectively, by forming the second insulation layer on the entire surface of the product.

Referring to FIG. 8B, the photoresist 411 may be formed on the product of the first region R3 in FIG. 8A, and the first sacrificial liner 405b in the second region R4 in FIG. 8A may be completely removed by a strip process. Next, the photoresist 411 may be removed.

Referring to FIG. 8C, a second sacrificial liner 413a and a third sub insulation liner 413b may be respectively formed in the first region R3 and the second region R4 by forming a third insulation layer on an entire surface of the product of FIG. 8B. After this, a third sacrificial liner 415a and the fourth insulation liner 415b may be formed in the first region R3 and the second region R4, respectively, by forming a fourth insulation layer on an entire surface of the product. And a sacrificial insulation layer 417a and the buried insulation layer 417b burying the trench may be formed in the first region R3 and the second region R4, respectively, by forming a fifth insulation layer on an entire surface of the product.

Referring to FIG. 8D, the buried insulation layer 417b on the top of the substrate 401 may be removed by performing a planarization process on an entire surface of a product of FIG. 8C. Next, by performing a strip process on an entire surface of the product, an entirety of the third sacrificial liner 415a in the first region R1 and a part of a top of the fourth insulation liner 415b in the second region R2 may be removed. In this case, a degree of the strip process may be adjusted so that a level of a top 415bT of the fourth insulation liner 415b may be lower than the level of the top of the substrate 401.

Referring to FIG. 8E, by performing a strip process on an entire surface of the product from FIG. 8D, the second sacrificial liners 413a of the first region R3 and a top of the third insulation liner 413b of the second region R4 may be removed. Accordingly, the semiconductor device 400 of FIG. 4 may be manufactured.

As described above, some example embodiments have been shown in attached drawings and specifications. Even though some particular terms were used to describe the example embodiments, it is to explain the some example embodiments of the present disclosure, but not to limit the scope of the present disclosure written in the claims. Therefore, those skilled in the art may understand that the present disclosure may be modified in various forms. Accordingly, the scope of the present disclosure may be determined by the attached claims.

What is claimed is:

1. A semiconductor device comprising:
a substrate including a first trench;
a first insulation liner on inner flanks of the first trench; and
a second insulation liner on inner flanks of a first sub trench, the first sub trench defined by the first insulation liner in the first trench, a top level of the second insulation liner that adjoins the inner flanks of the first sub trench in a direction perpendicular to a top surface of the substrate being different from the top surface of the substrate.

2. The semiconductor device of claim 1, wherein the top level of the second insulation liner is lower than the top surface of the substrate.

3. The semiconductor device of claim 2, wherein a top level of the first insulation liner that adjoins the inner flanks of the first trench in the direction perpendicular to the top surface of the substrate is lower than the top level of the second insulation liner.

4. The semiconductor device of claim 1, wherein the top level of the second insulation liner is higher than the top surface of the substrate.

5. The semiconductor device of claim 1, wherein the first insulation liner and the second insulation liner have etching selectivities with respect to each other.

6. The semiconductor device of claim 1, further comprising:
the substrate including a second trench;
a third insulation liner on inner flanks of the second trench; and
a fourth insulation liner on inner flanks of a second sub trench, the second sub trench defined by the third insulation liner in the second trench, a top level of the fourth insulation liner that adjoins the inner flanks of the second sub trench in the direction perpendicular to the top surface of the substrate being different from the top level of the second insulation liner.

7. The semiconductor device of claim 6, wherein
the top level of the fourth insulation liner that adjoins the inner flanks of the second sub trench in the direction perpendicular to the top surface of the substrate has a same height as the top surface of the substrate.

8. The semiconductor device of claim 6, wherein
the top level of the second insulation liner is lower than the top surface of the substrate, and
the top level of the fourth insulation liner is higher than the top surface of the substrate.

9. The semiconductor device of claim 6, further comprising:
a first sub insulation liner on inner flanks of a third sub trench, the third sub trench defined by the fourth insulation liner in the second trench, a top level of the first sub insulation liner that adjoins the inner flanks of the third sub trench in the direction perpendicular to the top surface of the substrate being substantially same as the top level of the second insulation liner; and
a second sub insulation liner on inner flanks of a fourth sub trench, the fourth sub trench defined by the first sub insulation liner in the second trench.

10. The semiconductor device of claim 1, wherein the second insulation liner fills an inner portion of the first sub trench.

11. The semiconductor device of claim 1, wherein the first insulation liner comprises an oxide film and the second insulation liner comprises a nitride film.

12. A semiconductor device comprising:
a substrate including a plurality of trenches;
a first insulation liner on inner flanks of each of the plurality of trenches; and
a second insulation liner on inner flanks of each of a plurality of first sub trenches, each of the plurality of first sub trenches defined by the first insulation liner in each of the plurality of trenches, the second insulation liners in at least two of the plurality of the trenches having different top levels in a direction perpendicular to a top surface of the substrate.

13. The semiconductor device of claim 12, wherein the second insulation liners having different top levels are in a cell region and a core/peri region, respectively.

14. The semiconductor device of claim 12, wherein the second insulation liners having different top levels are in a NMOS region and a PMOS region, respectively.

15. The semiconductor device of claim 14, wherein a height difference between a top level of one of the second insulation liners in the PMOS region and the top surface of the substrate is greater than a height difference between the top level of another of the second insulation liners in the NMOS region and the top surface of the substrate.

16. A semiconductor device comprising:
a substrate including a first trench;
a first insulation liner along a bottom and a sidewall of the first trench; and
a second insulation liner along a bottom and a sidewall of the first insulation liner, the second insulation liner having an etching selectivity with respect to the first insulation liner, a top level of the second insulation liner being different from a top surface of the substrate outside the first trench.

17. The semiconductor device of claim 16, wherein the top level of the second insulation liner is lower than the top surface of the substrate.

18. The semiconductor device of claim 16, wherein the top level of the second insulation liner is higher than the top surface of the substrate.

19. The semiconductor device of claim 16, wherein a top level of the first insulation liner is lower than the top level of the second insulation liner.

20. The semiconductor device of claim 16, further comprising:
the substrate including a second trench;
a third insulation liner along a bottom and a sidewall of the second trench; and
a fourth insulation liner along a bottom and a sidewall of the third insulation liner, the fourth insulation liner having an etching selectivity with respect to the third insulation liner, a top level of the fourth insulation liner being different from the top level of the second insulation liner.
